(19) United States
(12) Patent Application Publication
(10) Pub. No.: US 2025/0383523 A1
(43) Pub. Date: Dec. 18, 2025

(54) IMAGE SENSOR MOUNT AND SHIELDING

(71) Applicant: GoPro, Inc., San Mateo, CA (US)

(72) Inventors: Jesse Frost Patterson, Pacifica, CA (US); Nicholas Vitale, Foster City, CA (US); Mahshad Mosayebi, Palo Alto, CA (US)

(21) Appl. No.: 18/743,209

(22) Filed: Jun. 14, 2024

(51) Int. Cl. G02B 7/02; H05K 7/20

(52) U.S. Cl. CPC G02B 7/028; H05K 7/2039

(57) ABSTRACT

An image capture apparatus that includes a housing defining a cavity therein, an image capture device, a heat sink located in the cavity of the housing that contacts the image capture device, and a shield located in the cavity of the housing. The image capture device extends through the housing and includes an image sensor located within the cavity of the housing. The heat sink is configured to absorb heat generated by the image capture device. The shield at least partially encloses the image sensor and is coupled to the heat sink. The shield is configured to block electromagnetic waves generated external to the image sensor from the reaching the image sensor. The heat sink is configured to transfer the heat generated by the image capture device to the shield.

### TECHNICAL FIELD

This disclosure relates to an optical system, and more specifically, to an image capture device that includes an image sensor mount and shielding for an image sensor of the image capture device.

### BACKGROUND

Image capture apparatuses are used in a variety of applications. For example, image capture apparatuses may be a handheld camera or video recorder, or the image capture apparatuses may be part of (e.g., integrated into) a cell phone, drone, vehicle, the like, or a combination thereof. Such image capture apparatuses may typically include one or more lenses (or other such optical elements) and one or more image sensors. The lenses may capture content by receiving and focusing light, and the image sensors may convert the captured content into an electronic image signal that can be processed by an image signal processor within the image capture apparatus to generate an image. In addition to lenses and image sensors, the image capture apparatuses may include an array of internal components, both structural and electrical.

### SUMMARY

In one implementation an image capture apparatus includes a housing defining a cavity therein, an image capture device, a heat sink located in the cavity of the housing that contacts the image capture device, and a shield located in the cavity of the housing. The image capture device extends through the housing and includes an image sensor located within the cavity of the housing. The heat sink is configured to absorb heat generated by the image capture device. The shield at least partially encloses the image sensor and is coupled to the heat sink. The shield is configured to block electromagnetic waves generated external to the image sensor from the reaching the image sensor. Additionally, the heat sink is configured to transfer the heat generated by the image capture device to the shield.

In certain implementations, the image sensor may be positioned between the heat sink and the shield. The image capture device may include a lens barrel that extends through the housing and may extend through the heat sink.

In certain implementations, the image capture apparatus may also include a power module located in the cavity of the housing. The shield may be positioned between the heat sink and the power module. At least a portion of the shield may be positioned between the image sensor and the power module. The shield may be configured to transfer heat generated by the power module to the heat sink. Additionally, the shield may be spaced apart from the power module such that a space made from a thermal insulative material may be located therebetween.

In certain implementations, the shield may include a front face defining an opening therein and side faces connected to the front face. The front face and the side faces may define a cavity of the shield and the image sensor may be located within the cavity of the shield. The side faces may each include an alignment feature that is received by a respective receiving feature of the heat sink. The shield may further include a tab extending from one of the side faces that is configured to be coupled to the heat sink.

In another implementation, an image capture apparatus may include a housing defining a cavity therein, a heat sink located in the cavity of the housing, and an image capture device. The image capture device includes a lens barrel extending through the housing and located at least partially within the cavity of the housing and a lens barrel mount configured to couple the lens barrel to the image capture apparatus. The lens barrel mount includes a base, a first aperture defined by a tab of the lens barrel mount that extends from the base, a second aperture defined by the base, and a third aperture defined by the base and spaced apart from the second aperture. The lens barrel mount is configured to be mounted to the heat sink by fasteners extending through the first aperture, the second aperture, and the third aperture into the heat sink.

In certain implementations, the second aperture may be positioned along an outer edge of the base such that a circumference of the second aperture is open to the outer edge of the base. Additionally, the third aperture may be an open-ended and slotted hole.

In certain implementations, the lens barrel mount may be configured to align the lens barrel along an optical axis of the image capture device when the lens barrel mount is mounted to the heat sink.

In certain implementations, the lens barrel mount may further include a barrel extending from the base that defines an opening therein. The barrel of the lens barrel mount may be configured to receive the lens barrel. Additionally, the barrel of the lens barrel mount and the lens barrel may be configured to be aligned along an optical axis of the image capture device.

In another implementation, an image capture apparatus includes a housing, an image capture device, a heat sink located in the housing that contacts the image capture device, and a shield located in the housing and that defines a cavity therein. The image capture device includes a lens barrel, an image sensor, and a lens barrel mount. The lens barrel mount includes a base and a barrel extending from the base that defines an opening therein that is configured to receive the lens barrel and align the lens barrel with an optical axis of the image capture device. Additionally, the image sensor and the lens barrel mount are positioned in the cavity of the shield, and the image sensor is coupled to the lens barrel mount.

In certain implementations, the shield and the lens barrel mount may be coupled to the heat sink.

In certain implementations, the image capture device may further include a removable lens cover that may be coupled to the heat sink. The heat sink may include a bayonet that is configured to releasably couple the removable lens cover to the heat sink.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIGS. 1A-1B are isometric views of an example of an image capture apparatus.

FIGS. 2A-2B are isometric views of another example of an image capture apparatus.

FIG. 3 is a top view of another example of an image capture apparatus.

FIGS. 4A-4B are isometric views of another example of an image capture apparatus.

FIG. 5 is a block diagram of electronic components of an image capture apparatus.

FIG. 6 is an isometric view of another example of an image capture apparatus.

FIG. 7A is an isometric view of the image capture apparatus shown in FIG. 6 with the housing removed.

FIG. 7B is a close-up view of the image capture apparatus shown FIG. 6 with the housing removed.

FIG. 8 is a perspective view of an image capture device of the image capture apparatus shown in FIG. 6.

FIG. 9 is a cross-sectional view of the image capture apparatus shown in FIG. 7A taken along line 9-9.

FIG. 10 is an exploded view of the image capture device shown in FIG. 8.

FIGS. 11A-11B are isometric views of a shield of an image capture device.

FIGS. 12A-12B are isometric views of a lens barrel mount of an image capture device.

### DETAILED DESCRIPTION

Image capture apparatuses may include an image capture device disposed therein that is configured to capture content (e.g., pictures and/or video). The image capture device may include one or more lenses that are fixed within the image capture device (e.g., internal lenses integrated with, or coupled to, a lens barrel of the image capture device) and one or more lenses that are removably and/or interchangeable (e.g., a replaceable lens cover positioned external of the lens barrel). The lenses may be aligned along an optical axis of the image capture device such that the lenses may capture content by receiving and focusing light. An image sensor may then convert the captured content into an electronic image signal that can be processed to generate an image. To facilitate such operation of the image capture device, the image capture apparatus may also include one or more power modules (e.g., a battery) to power the image capture device.

In order for images and/or videos to be accurately captured, the lenses and the image sensor may be aligned along the optical axis. The lenses and the image sensor may be subject to build tolerances that, if not followed, could cause misalignment and negatively impact capture of the images or videos. Additionally, if the image capture apparatus is accidentally dropped or impacted, the lenses and the image sensor may be damaged or may become misaligned, thereby negatively impacting the capture of the images or the videos.

Moreover, electronic interference caused by external devices may negatively impact the conversion of the captured content into an electronic image signal that may be used to generate an image. For example, electromagnetic radiation (e.g., electromagnetic waves) emitted by other devices or other external sources may interfere with the image sensor of the image capture device, which may negatively affect the performance of the image sensor and thereby result in a blurry or distorted resulting image. Similarly, use of the image capture apparatus may result in increased operating temperatures, which may also negatively impact the performance of the image sensor and/or the image capture device as a whole.

An image capture apparatus and an image capture device are described herein that achieve and/or maintain proper alignment between the lens and the image sensor of the image capture device so that images and/or videos captured are clear and complete without distortion. Furthermore, the image capture device may provide protection (e.g., shielding) from electromagnetic radiation to deflect and/or absorb electromagnetic waves that may otherwise interfere with the image sensor. Additionally, the image capture apparatus and/or the image capture device may provide improved heat dissipation to maintain operating temperatures of the image capture apparatus within a desired temperature range.

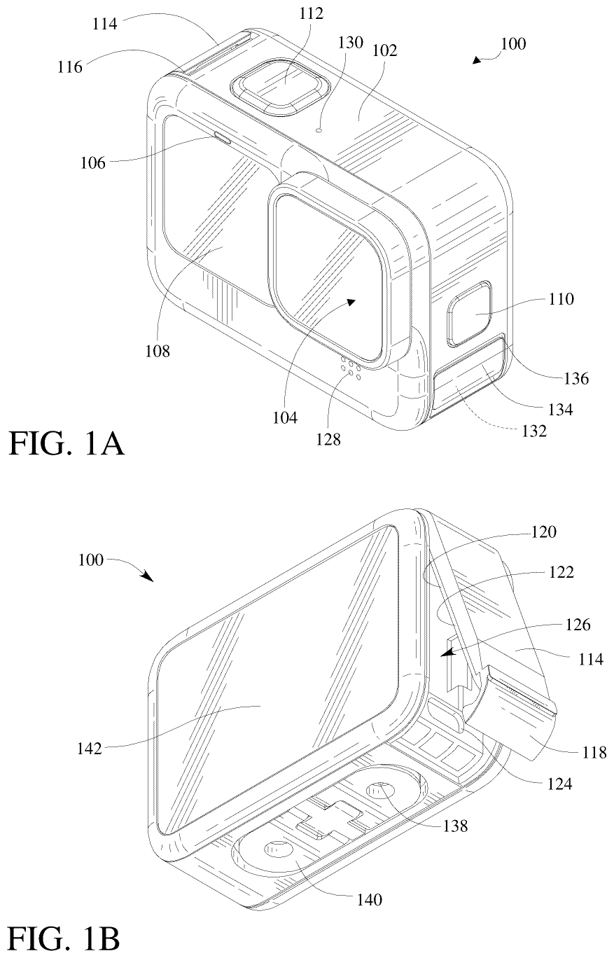

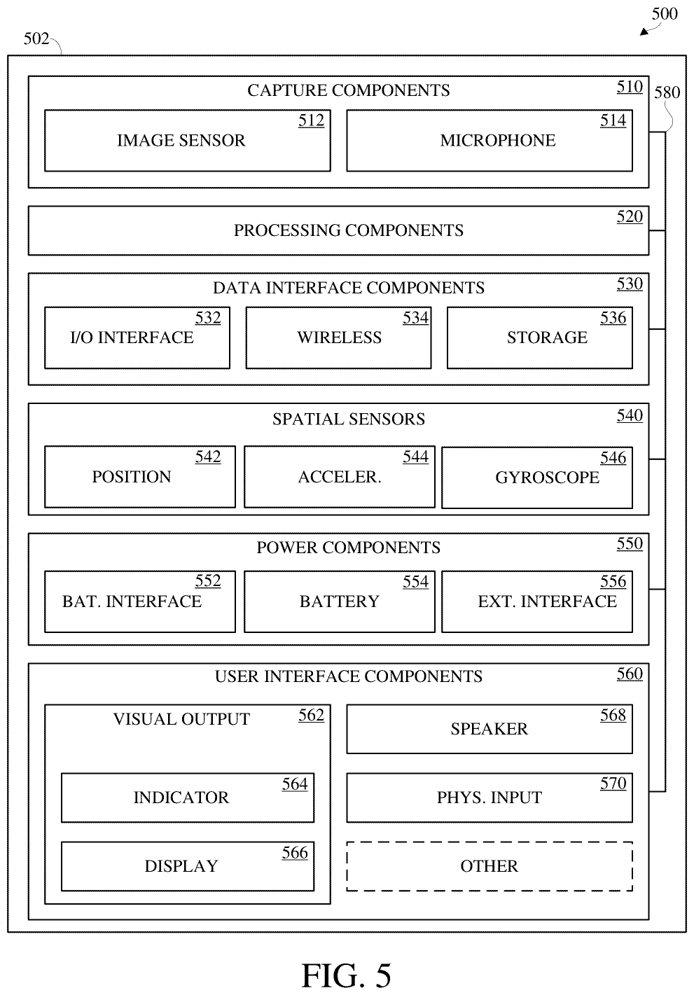

FIGS. 1A-1B are isometric views of an example of an image capture apparatus 100. The image capture apparatus 100 includes a body 102, an image capture device 104, an indicator 106, a display 108, a mode button 110, a shutter button 112, a door 114, a hinge mechanism 116, a latch mechanism 118, a seal 120, a battery interface 122, a data interface 124, a battery receptacle 126, microphones 128, 130, 132, a speaker 138, an interconnect mechanism 140, and a display 142. Although not expressly shown in FIGS. 1A-1B, the image capture apparatus 100 includes internal electronics, such as imaging electronics, power electronics, and the like, internal to the body 102 for capturing images and performing other functions of the image capture apparatus 100. An example showing internal electronics is shown in FIG. 5. The arrangement of the components of the image capture apparatus 100 shown in FIGS. 1A-1B is an example, other arrangements of elements may be used, except as is described herein or as is otherwise clear from context.

The body 102 of the image capture apparatus 100 may be made of a rigid material such as plastic, aluminum, steel, or fiberglass. Other materials may be used. The image capture device 104 is structured on a front surface of, and within, the body 102. The image capture device 104 includes a lens. The lens of the image capture device 104 receives light incident upon the lens of the image capture device 104 and directs the received light onto an image sensor of the image capture device 104 internal to the body 102. The image capture apparatus 100 may capture one or more images, such as a sequence of images, such as video. The image capture apparatus 100 may store the captured images and video for subsequent display, playback, or transfer to an external device. Although one image capture device 104 is shown in FIG. 1A, the image capture apparatus 100 may include multiple image capture devices, which may be structured on respective surfaces of the body 102.

As shown in FIG. 1A, the image capture apparatus 100 includes the indicator 106 structured on the front surface of the body 102. The indicator 106 may output, or emit, visible light, such as to indicate a status of the image capture apparatus 100. For example, the indicator 106 may be a light-emitting diode (LED). Although one indicator 106 is shown in FIG. 1A, the image capture apparatus 100 may include multiple indictors structured on respective surfaces of the body 102.

As shown in FIG. 1A, the image capture apparatus 100 includes the display 108 structured on the front surface of the body 102. The display 108 outputs, such as presents or displays, such as by emitting visible light, information, such as to show image information such as image previews, live video capture, or status information such as battery life, camera mode, elapsed time, and the like. In some implementations, the display 108 may be an interactive display, which may receive, detect, or capture input, such as user input representing user interaction with the image capture apparatus 100. In some implementations, the display 108 may be omitted or combined with another component of the image capture apparatus 100.

As shown in FIG. 1A, the image capture apparatus 100 includes the mode button 110 structured on a side surface of the body 102. Although described as a button, the mode button 110 may be another type of input device, such as a switch, a toggle, a slider, or a dial. Although one mode button 110 is shown in FIG. 1A, the image capture apparatus 100 may include multiple mode, or configuration, buttons structured on respective surfaces of the body 102. In some implementations, the mode button 110 may be omitted or combined with another component of the image capture apparatus 100. For example, the display 108 may be an interactive, such as touchscreen, display, and the mode button 110 may be physically omitted and functionally combined with the display 108.

As shown in FIG. 1A, the image capture apparatus 100 includes the shutter button 112 structured on a top surface of the body 102. The shutter button 112 may be another type of input device, such as a switch, a toggle, a slider, or a dial. The image capture apparatus 100 may include multiple shutter buttons structured on respective surfaces of the body 102. In some implementations, the shutter button 112 may be omitted or combined with another component of the image capture apparatus 100.

The mode button 110, the shutter button 112, or both, obtain input data, such as user input data in accordance with user interaction with the image capture apparatus 100. For example, the mode button 110, the shutter button 112, or both, may be used to turn the image capture apparatus 100 on and off, scroll through modes and settings, and select modes and change settings.

As shown in FIG. 1B, the image capture apparatus 100 includes the door 114 coupled to the body 102, such as using the hinge mechanism 116 (FIG. 1A). The door 114 may be secured to the body 102 using the latch mechanism 118 that releasably engages the body 102 at a position generally opposite the hinge mechanism 116. The door 114 includes the seal 120 and the battery interface 122. Although one door 114 is shown in FIG. 1A, the image capture apparatus 100 may include multiple doors respectively forming respective surfaces of the body 102, or portions thereof. The door 114 may be removable from the body 102 by releasing the latch mechanism 118 from the body 102 and decoupling the hinge mechanism 116 from the body 102.

In FIG. 1B, the door 114 is shown in a partially open position such that the data interface 124 is accessible for communicating with external devices and the battery receptacle 126 is accessible for placement or replacement of a battery. In FIG. 1A, the door 114 is shown in a closed position. In implementations in which the door 114 is in the closed position, the seal 120 engages a flange (not shown) to provide an environmental seal and the battery interface 122 engages the battery (not shown) to secure the battery in the battery receptacle 126.

As shown in FIG. 1B, the image capture apparatus 100 includes the battery receptacle 126 structured to form a portion of an interior surface of the body 102. The battery receptacle 126 includes operative connections for power transfer between the battery and the image capture apparatus 100. In some implementations, the battery receptacle 126 may be omitted. The image capture apparatus 100 may include multiple battery receptacles.

As shown in FIG. 1A, the image capture apparatus 100 includes a first microphone 128 structured on a front surface of the body 102, a second microphone 130 structured on a top surface of the body 102, and a third microphone 132 structured on a side surface of the body 102. The third microphone 132, which may be referred to as a drain microphone and is indicated as hidden in dotted line, is located behind a drain cover 134, surrounded by a drain channel 136, and can drain liquid from audio components of the image capture apparatus 100. The image capture apparatus 100 may include other microphones on other surfaces of the body 102. The microphones 128, 130, 132 receive and record audio, such as in conjunction with capturing video or separate from capturing video. In some implementations, one or more of the microphones 128, 130, 132 may be omitted or combined with other components of the image capture apparatus 100.

As shown in FIG. 1B, the image capture apparatus 100 includes the speaker 138 structured on a bottom surface of the body 102. The speaker 138 outputs or presents audio, such as by playing back recorded audio or emitting sounds associated with notifications. The image capture apparatus 100 may include multiple speakers structured on respective surfaces of the body 102.

As shown in FIG. 1B, the image capture apparatus 100 includes the interconnect mechanism 140 structured on a bottom surface of the body 102. The interconnect mechanism 140 removably connects the image capture apparatus 100 to an external structure, such as a handle grip, another mount, or a securing device. The interconnect mechanism 140 includes folding protrusions configured to move between a nested or collapsed position as shown in FIG. 1B and an extended or open position. The folding protrusions of the interconnect mechanism 140 in the extended or open position may be coupled to reciprocal protrusions of other devices such as handle grips, mounts, clips, or like devices. The image capture apparatus 100 may include multiple interconnect mechanisms structured on, or forming a portion of, respective surfaces of the body 102. In some implementations, the interconnect mechanism 140 may be omitted.

As shown in FIG. 1B, the image capture apparatus 100 includes the display 142 structured on, and forming a portion of, a rear surface of the body 102. The display 142 outputs, such as presents or displays, such as by emitting visible light, data, such as to show image information such as image previews, live video capture, or status information such as battery life, camera mode, elapsed time, and the like. In some implementations, the display 142 may be an interactive display, which may receive, detect, or capture input, such as user input representing user interaction with the image capture apparatus 100. The image capture apparatus 100 may include multiple displays structured on respective surfaces of the body 102, such as the displays 108, 142 shown in FIGS. 1A-1B. In some implementations, the display 142 may be omitted or combined with another component of the image capture apparatus 100.

The image capture apparatus 100 may include features or components other than those described herein, such as other buttons or interface features. In some implementations, interchangeable lenses, cold shoes, and hot shoes, or a combination thereof, may be coupled to or combined with the image capture apparatus 100. For example, the image capture apparatus 100 may communicate with an external device, such as an external user interface device, via a wired or wireless computing communication link, such as via the data interface 124. The computing communication link may be a direct computing communication link or an indirect computing communication link, such as a link including another device or a network, such as the Internet. The image capture apparatus 100 may transmit images to the external device via the computing communication link.

The external device may store, process, display, or combination thereof, the images. The external user interface device may be a computing device, such as a smartphone, a tablet computer, a smart watch, a portable computer, personal computing device, or another device or combination of devices configured to receive user input, communicate information with the image capture apparatus 100 via the computing communication link, or receive user input and communicate information with the image capture apparatus 100 via the computing communication link. The external user interface device may implement or execute one or more applications to manage or control the image capture apparatus 100. For example, the external user interface device may include an application for controlling camera configuration, video acquisition, video display, or any other configurable or controllable aspect of the image capture apparatus 100. In some implementations, the external user interface device may generate and share, such as via a cloud-based or social media service, one or more images or video clips. In some implementations, the external user interface device may display unprocessed or minimally processed images or video captured by the image capture apparatus 100 contemporaneously with capturing the images or video by the image capture apparatus 100, such as for shot framing or live preview.

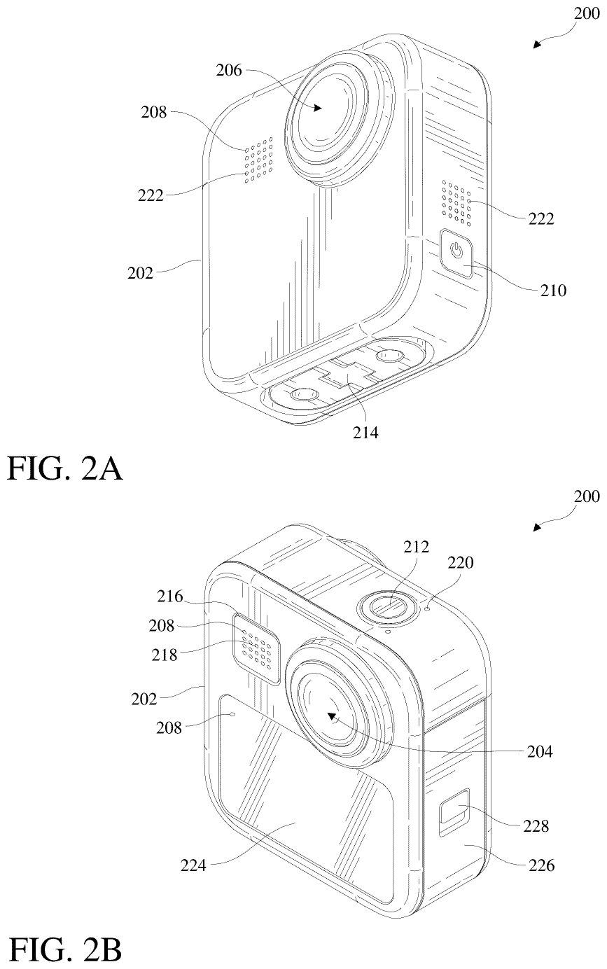

FIGS. 2A-2B illustrate another example of an image capture apparatus 200. The image capture apparatus 200 is similar to the image capture apparatus 100 shown in FIGS. 1A-1B. The image capture apparatus 200 includes a body 202, a first image capture device 204, a second image capture device 206, indicators 208, a mode button 210, a shutter button 212, an interconnect mechanism 214, a drainage channel 216, audio components 218, 220, 222, a display 224, and a door 226 including a release mechanism 228. The arrangement of the components of the image capture apparatus 200 shown in FIGS. 2A-2B is an example, other arrangements of elements may be used.

The body 202 of the image capture apparatus 200 may be similar to the body 102 shown in FIGS. 1A-1B. The first image capture device 204 is structured on a front surface of the body 202. The first image capture device 204 includes a first lens. The first image capture device 204 may be similar to the image capture device 104 shown in FIG. 1A. As shown in FIG. 2A, the image capture apparatus 200 includes the second image capture device 206 structured on a rear surface of the body 202. The second image capture device 206 includes a second lens. The second image capture device 206 may be similar to the image capture device 104 shown in FIG. 1A. The image capture devices 204, 206 are disposed on opposing surfaces of the body 202, for example, in a back-to-back configuration, Janus configuration, or offset Janus configuration. The image capture apparatus 200 may include other image capture devices structured on respective surfaces of the body 202.

As shown in FIG. 2B, the image capture apparatus 200 includes the indicators 208 associated with the audio component 218 and the display 224 on the front surface of the body 202. The indicators 208 may be similar to the indicator 106 shown in FIG. 1A. For example, one of the indicators 208 may indicate a status of the first image capture device 204 and another one of the indicators 208 may indicate a status of the second image capture device 206. Although two indicators 208 are shown in FIGS. 2A-2B, the image capture apparatus 200 may include other indictors structured on respective surfaces of the body 202.

As shown in FIGS. 2A-2B, the image capture apparatus 200 includes input mechanisms including the mode button 210, structured on a side surface of the body 202, and the shutter button 212, structured on a top surface of the body 202. The mode button 210 may be similar to the mode button 110 shown in FIG. 1B. The shutter button 212 may be similar to the shutter button 112 shown in FIG. 1A.

The image capture apparatus 200 includes internal electronics (not expressly shown), such as imaging electronics, power electronics, and the like, internal to the body 202 for capturing images and performing other functions of the image capture apparatus 200. An example showing internal electronics is shown in FIG. 5.

As shown in FIGS. 2A-2B, the image capture apparatus 200 includes the interconnect mechanism 214 structured on a bottom surface of the body 202. The interconnect mechanism 214 may be similar to the interconnect mechanism 140 shown in FIG. 1B.

As shown in FIG. 2B, the image capture apparatus 200 includes the drainage channel 216 for draining liquid from audio components of the image capture apparatus 200.

As shown in FIGS. 2A-2B, the image capture apparatus 200 includes the audio components 218, 220, 222, respectively structured on respective surfaces of the body 202. The audio components 218, 220, 222 may be similar to the microphones 128, 130, 132 and the speaker 138 shown in FIGS. 1A-1B. One or more of the audio components 218, 220, 222 may be, or may include, audio sensors, such as microphones, to receive and record audio signals, such as voice commands or other audio, in conjunction with capturing images or video. One or more of the audio components 218, 220, 222 may be, or may include, an audio presentation component that may present, or play, audio, such as to provide notifications or alerts.

As shown in FIGS. 2A-2B, a first audio component 218 is located on a front surface of the body 202, a second audio component 220 is located on a top surface of the body 202, and a third audio component 222 is located on a back surface of the body 202. Other numbers and configurations for the audio components 218, 220, 222 may be used. For example, the audio component 218 may be a drain microphone surrounded by the drainage channel 216 and adjacent to one of the indicators 208 as shown in FIG. 2B.

As shown in FIG. 2B, the image capture apparatus 200 includes the display 224 structured on a front surface of the body 202. The display 224 may be similar to the displays 108, 142 shown in FIGS. 1A-1B. The display 224 may include an I/O interface. The display 224 may include one or more of the indicators 208. The display 224 may receive touch inputs. The display 224 may display image information during video capture. The display 224 may provide status information to a user, such as status information indicating battery power level, memory card capacity, time elapsed for a recorded video, etc. The image capture apparatus 200 may include multiple displays structured on respective surfaces of the body 202. In some implementations, the display 224 may be omitted or combined with another component of the image capture apparatus 200.

As shown in FIG. 2B, the image capture apparatus 200 includes the door 226 structured on, or forming a portion of, the side surface of the body 202. The door 226 may be similar to the door 114 shown in FIG. 1A. For example, the door 226 shown in FIG. 2A includes a release mechanism 228. The release mechanism 228 may include a latch, a button, or other mechanism configured to receive a user input that allows the door 226 to change position. The release mechanism 228 may be used to open the door 226 for a user to access a battery, a battery receptacle, an I/O interface, a memory card interface, etc.

In some embodiments, the image capture apparatus 200 may include features or components other than those described herein, some features or components described herein may be omitted, or some features or components described herein may be combined. For example, the image capture apparatus 200 may include additional interfaces or different interface features, interchangeable lenses, cold shoes, or hot shoes.

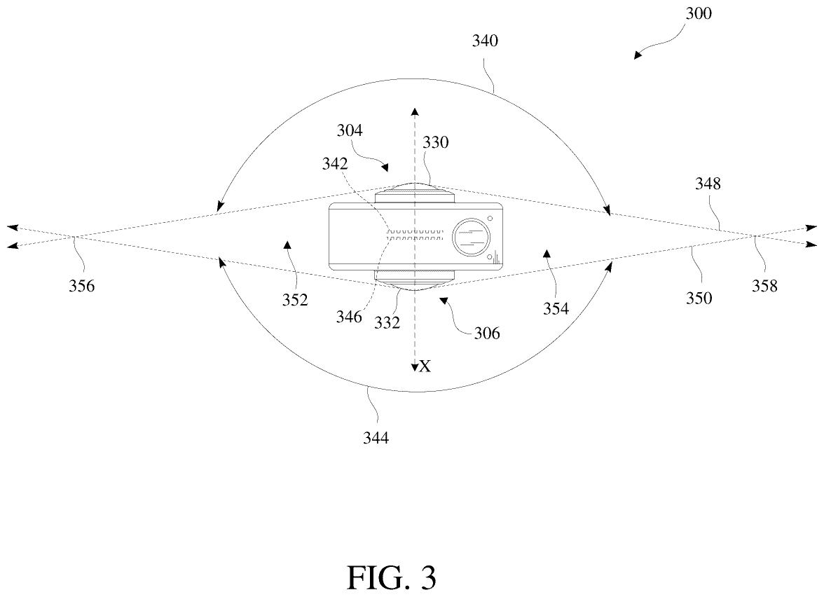

FIG. 3 is a top view of an image capture apparatus 300. The image capture apparatus 300 is similar to the image capture apparatus 200 of FIGS. 2A-2B and is configured to capture spherical images.

As shown in FIG. 3, a first image capture device 304 includes a first lens 330 and a second image capture device 306 includes a second lens 332. For example, the first image capture device 304 may capture a first image, such as a first hemispheric, or hyper-hemispherical, image, the second image capture device 306 may capture a second image, such as a second hemispheric, or hyper-hemispherical, image, and the image capture apparatus 300 may generate a spherical image incorporating or combining the first image and the second image, which may be captured concurrently, or substantially concurrently.

The first image capture device 304 defines a first field-of-view 340 wherein the first lens 330 of the first image capture device 304 receives light. The first lens 330 directs the received light corresponding to the first field-of-view 340 onto a first image sensor 342 of the first image capture device 304. For example, the first image capture device 304 may include a first lens barrel (not expressly shown), extending from the first lens 330 to the first image sensor 342.

The second image capture device 306 defines a second field-of-view 344 wherein the second lens 332 receives light. The second lens 332 directs the received light corresponding to the second field-of-view 344 onto a second image sensor 346 of the second image capture device 306. For example, the second image capture device 306 may include a second lens barrel (not expressly shown), extending from the second lens 332 to the second image sensor 346.

A boundary 348 of the first field-of-view 340 is shown using broken directional lines. A boundary 350 of the second field-of-view 344 is shown using broken directional lines. As shown, the image capture devices 304, 306 are arranged in a back-to-back (Janus) configuration such that the lenses 330, 332 face in opposite directions, and such that the image capture apparatus 300 may capture spherical images. The first image sensor 342 captures a first hyper-hemispherical image plane from light entering the first lens 330. The second image sensor 346 captures a second hyper-hemispherical image plane from light entering the second lens 332.

As shown in FIG. 3, the fields-of-view 340, 344 partially overlap such that the combination of the fields-of-view 340, 344 forms a spherical field-of-view, except that one or more uncaptured areas 352, 354 may be outside of the fields-of-view 340, 344 of the lenses 330, 332. Light emanating from or passing through the uncaptured areas 352, 354, which may be proximal to the image capture apparatus 300, may be obscured from the lenses 330, 332 and the corresponding image sensors 342, 346, such that content corresponding to the uncaptured areas 352, 354 may be omitted from images captured by the image capture apparatus 300. In some implementations, the image capture devices 304, 306, or the lenses 330, 332 thereof, may be configured to minimize the uncaptured areas 352, 354.

Examples of points of transition, or overlap points, from the uncaptured areas 352, 354 to the overlapping portions of the fields-of-view 340, 344 are shown at 356, 358.

Images contemporaneously captured by the respective image sensors 342, 346 may be combined to form a combined image, such as a spherical image. Generating a combined image may include correlating the overlapping regions captured by the respective image sensors 342, 346, aligning the captured fields-of-view 340, 344, and stitching the images together to form a cohesive combined image. Stitching the images together may include correlating the overlap points 356, 358 with respective locations in corresponding images captured by the image sensors 342, 346. Although a planar view of the fields-of-view 340, 344 is shown in FIG. 3, the fields-of-view 340, 344 are hyper-hemispherical.

A change in the alignment, such as position, tilt, or a combination thereof, of the image capture devices 304, 306, such as of the lenses 330, 332, the image sensors 342, 346, or both, may change the relative positions of the respective fields-of-view 340, 344, may change the locations of the overlap points 356, 358, such as with respect to images captured by the image sensors 342, 346, and may change the uncaptured areas 352, 354, which may include changing the uncaptured areas 352, 354 unequally.

Incomplete or inaccurate information indicating the alignment of the image capture devices 304, 306, such as the locations of the overlap points 356, 358, may decrease the accuracy, efficiency, or both of generating a combined image. In some implementations, the image capture apparatus 300 may maintain information indicating the location and orientation of the image capture devices 304, 306, such as of the lenses 330, 332, the image sensors 342, 346, or both, such that the fields-of-view 340, 344, the overlap points 356, 358, or both may be accurately determined, which may improve the accuracy, efficiency, or both of generating a combined image.

The lenses 330, 332 may be aligned along an axis X as shown, laterally offset from each other (not shown), off-center from a central axis of the image capture apparatus 300 (not shown), or laterally offset and off-center from the central axis (not shown). Whether through use of offset or through use of compact image capture devices 304, 306, a reduction in distance between the lenses 330, 332 along the axis X may improve the overlap in the fields-of-view 340, 344, such as by reducing the uncaptured areas 352, 354.

Images or frames captured by the image capture devices 304, 306 may be combined, merged, or stitched together to produce a combined image, such as a spherical or panoramic image, which may be an equirectangular planar image. In some implementations, generating a combined image may include use of techniques such as noise reduction, tone mapping, white balancing, or other image correction. In some implementations, pixels along a stitch boundary, which may correspond with the overlap points 356, 358, may be matched accurately to minimize boundary discontinuities.

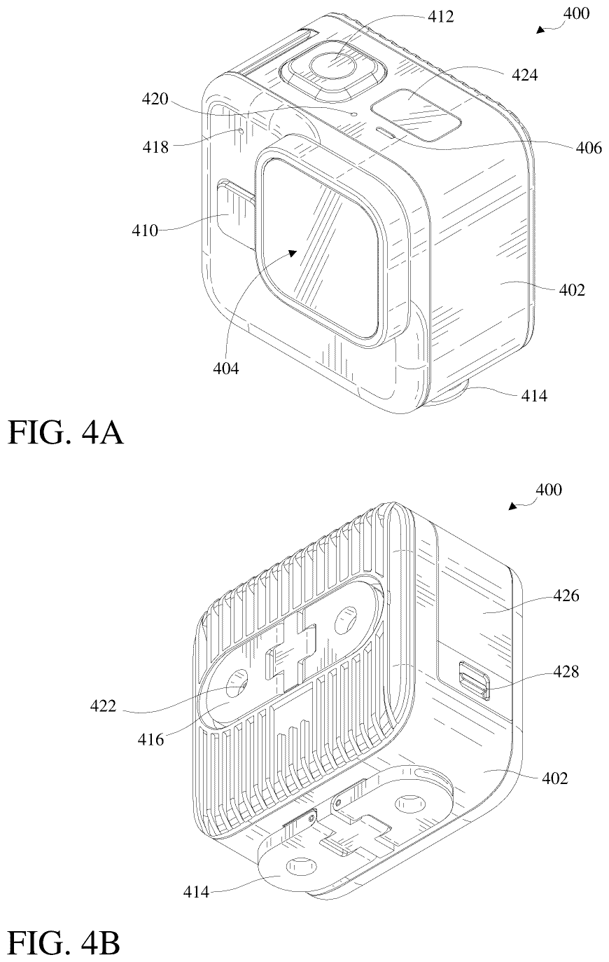

FIGS. 4A-4B illustrate another example of an image capture apparatus 400. The image capture apparatus 400 is similar to the image capture apparatus 100 shown in FIGS. 1A-1B and to the image capture apparatus 200 shown in FIGS. 2A-2B. The image capture apparatus 400 includes a body 402, an image capture device 404, an indicator 406, a mode button 410, a shutter button 412, interconnect mechanisms 414, 416, audio components 418, 420, 422, a display 424, and a door 426 including a release mechanism 428. The arrangement of the components of the image capture apparatus 400 shown in FIGS. 4A-4B is an example, other arrangements of elements may be used.

The body 402 of the image capture apparatus 400 may be similar to the body 102 shown in FIGS. 1A-1B. The image capture device 404 is structured on a front surface of the body 402. The image capture device 404 includes a lens and may be similar to the image capture device 104 shown in FIG. 1A.

As shown in FIG. 4A, the image capture apparatus 400 includes the indicator 406 on a top surface of the body 402. The indicator 406 may be similar to the indicator 106 shown in FIG. 1A. The indicator 406 may indicate a status of the image capture device 204. Although one indicator 406 is shown in FIGS. 4A, the image capture apparatus 400 may include other indictors structured on respective surfaces of the body 402.

As shown in FIGS. 4A, the image capture apparatus 400 includes input mechanisms including the mode button 410, structured on a front surface of the body 402, and the shutter button 412, structured on a top surface of the body 402. The mode button 410 may be similar to the mode button 110 shown in FIG. 1B. The shutter button 412 may be similar to the shutter button 112 shown in FIG. 1A.

The image capture apparatus 400 includes internal electronics (not expressly shown), such as imaging electronics, power electronics, and the like, internal to the body 402 for capturing images and performing other functions of the image capture apparatus 400. An example showing internal electronics is shown in FIG. 5.

As shown in FIGS. 4A-4B, the image capture apparatus 400 includes the interconnect mechanisms 414, 416, with a first interconnect mechanism 414 structured on a bottom surface of the body 402 and a second interconnect mechanism 416 disposed within a rear surface of the body 402. The interconnect mechanisms 414, 416 may be similar to the interconnect mechanism 140 shown in FIG. 1B and the interconnect mechanism 214 shown in FIG. 2A.

As shown in FIGS. 4A-4B, the image capture apparatus 400 includes the audio components 418, 420, 422 respectively structured on respective surfaces of the body 402. The audio components 418, 420, 422 may be similar to the microphones 128, 130, 132 and the speaker 138 shown in FIGS. 1A-1B. One or more of the audio components 418, 420, 422 may be, or may include, audio sensors, such as microphones, to receive and record audio signals, such as voice commands or other audio, in conjunction with capturing images or video. One or more of the audio components 418, 420, 422 may be, or may include, an audio presentation component that may present, or play, audio, such as to provide notifications or alerts.

As shown in FIGS. 4A-4B, a first audio component 418 is located on a front surface of the body 402, a second audio component 420 is located on a top surface of the body 402, and a third audio component 422 is located on a rear surface of the body 402. Other numbers and configurations for the audio components 418, 420, 422 may be used.

As shown in FIG. 4A, the image capture apparatus 400 includes the display 424 structured on a front surface of the body 402. The display 424 may be similar to the displays 108, 142 shown in FIGS. 1A-1B. The display 424 may include an I/O interface. The display 424 may receive touch inputs. The display 424 may display image information during video capture. The display 424 may provide status information to a user, such as status information indicating battery power level, memory card capacity, time elapsed for a recorded video, etc. The image capture apparatus 400 may include multiple displays structured on respective surfaces of the body 402. In some implementations, the display 424 may be omitted or combined with another component of the image capture apparatus 200.

As shown in FIG. 4B, the image capture apparatus 400 includes the door 426 structured on, or forming a portion of, the side surface of the body 402. The door 426 may be similar to the door 226 shown in FIG. 2B. The door 426 shown in FIG. 4B includes the release mechanism 428. The release mechanism 428 may include a latch, a button, or other mechanism configured to receive a user input that allows the door 426 to change position. The release mechanism 428 may be used to open the door 426 for a user to access a battery, a battery receptacle, an I/O interface, a memory card interface, etc.

In some embodiments, the image capture apparatus 400 may include features or components other than those described herein, some features or components described herein may be omitted, or some features or components described herein may be combined. For example, the image capture apparatus 400 may include additional interfaces or different interface features, interchangeable lenses, cold shoes, or hot shoes.

FIG. 5 is a block diagram of electronic components in an image capture apparatus 500. The image capture apparatus 500 may be a single-lens image capture device, a multi-lens image capture device, or variations thereof, including an image capture apparatus with multiple capabilities such as the use of interchangeable integrated sensor lens assemblies. Components, such as electronic components, of the image capture apparatus 100 shown in FIGS. 1A-1B, the image capture apparatus 200 shown in FIGS. 2A-2B, the image capture apparatus 300 shown in FIG. 3, or the image capture apparatus 400 shown in FIGS. 4A-4B, may be implemented as shown in FIG. 5.

The image capture apparatus 500 includes a body 502. The body 502 may be similar to the body 102 shown in FIGS. 1A-1B, the body 202 shown in FIGS. 2A-2B, or the body 402 shown in FIGS. 4A-4B. The body 502 includes electronic components such as capture components 510, processing components 520, data interface components 530, spatial sensors 540, power components 550, user interface components 560, and a bus 580.

The capture components 510 include an image sensor 512 for capturing images. Although one image sensor 512 is shown in FIG. 5, the capture components 510 may include multiple image sensors. The image sensor 512 may be similar to the image sensors 342, 346 shown in FIG. 3. The image sensor 512 may be, for example, a charge-coupled device (CCD) sensor, an active pixel sensor (APS), a complementary metal-oxide-semiconductor (CMOS) sensor, or an N-type metal-oxide-semiconductor (NMOS) sensor. The image sensor 512 detects light, such as within a defined spectrum, such as the visible light spectrum or the infrared spectrum, incident through a corresponding lens such as the first lens 330 with respect to the first image sensor 342 or the second lens 332 with respect to the second image sensor 346 as shown in FIG. 3. The image sensor 512 captures detected light as image data and conveys the captured image data as electrical signals (image signals or image data) to the other components of the image capture apparatus 500, such as to the processing components 520, such as via the bus 580.

The capture components 510 include a microphone 514 for capturing audio. Although one microphone 514 is shown in FIG. 5, the capture components 510 may include multiple microphones. The microphone 514 detects and captures, or records, sound, such as sound waves incident upon the microphone 514. The microphone 514 may detect, capture, or record sound in conjunction with capturing images by the image sensor 512. The microphone 514 may detect sound to receive audible commands to control the image capture apparatus 500. The microphone 514 may be similar to the microphones 128, 130, 132 shown in FIGS. 1A-1B, the audio components 218, 220, 222 shown in FIGS. 2A-2B, or the audio components 418, 420, 422 shown in FIGS. 4A-4B.

The processing components 520 perform image signal processing, such as filtering, tone mapping, or stitching, to generate, or obtain, processed images, or processed image data, based on image data obtained from the image sensor 512. The processing components 520 may include one or more processors having single or multiple processing cores. In some implementations, the processing components 520 may include, or may be, an application specific integrated circuit (ASIC) or a digital signal processor (DSP). For example, the processing components 520 may include a custom image signal processor. The processing components 520 conveys data, such as processed image data, with other components of the image capture apparatus 500 via the bus 580. In some implementations, the processing components 520 may include an encoder, such as an image or video encoder that may encode, decode, or both, the image data, such as for compression coding, transcoding, or a combination thereof.

Although not shown expressly in FIG. 5, the processing components 520 may include memory, such as a random-access memory (RAM) device, which may be non-transitory computer-readable memory. The memory of the processing components 520 may include executable instructions and data that can be accessed by the processing components 520.

The data interface components 530 communicates with other, such as external, electronic devices, such as a remote control, a smartphone, a tablet computer, a laptop computer, a desktop computer, or an external computer storage device. For example, the data interface components 530 may receive commands to operate the image capture apparatus 500. In another example, the data interface components 530 may transmit image data to transfer the image data to other electronic devices. The data interface components 530 may be configured for wired communication, wireless communication, or both. As shown, the data interface components 530 include an I/O interface 532, a wireless data interface 534, and a storage interface 536. In some implementations, one or more of the I/O interface 532, the wireless data interface 534, or the storage interface 536 may be omitted or combined.

The I/O interface 532 may send, receive, or both, wired electronic communications signals. For example, the I/O interface 532 may be a universal serial bus (USB) interface, such as USB type-C interface, a high-definition multimedia interface (HDMI), a FireWire interface, a digital video interface link, a display port interface link, a Video Electronics Standards Associated (VESA) digital display interface link, an Ethernet link, or a Thunderbolt link. Although one I/O interface 532 is shown in FIG. 5, the data interface components 530 include multiple I/O interfaces. The I/O interface 532 may be similar to the data interface 124 shown in FIG. 1B.

The wireless data interface 534 may send, receive, or both, wireless electronic communications signals. The wireless data interface 534 may be a Bluetooth interface, a ZigBee interface, a Wi-Fi interface, an infrared link, a cellular link, a near field communications (NFC) link, or an Advanced Network Technology interoperability (ANT+) link. Although one wireless data interface 534 is shown in FIG. 5, the data interface components 530 include multiple wireless data interfaces. The wireless data interface 534 may be similar to the data interface 124 shown in FIG. 1B.

The storage interface 536 may include a memory card connector, such as a memory card receptacle, configured to receive and operatively couple to a removable storage device, such as a memory card, and to transfer, such as read, write, or both, data between the image capture apparatus 500 and the memory card, such as for storing images, recorded audio, or both captured by the image capture apparatus 500 on the memory card. Although one storage interface 536 is shown in FIG. 5, the data interface components 530 include multiple storage interfaces. The storage interface 536 may be similar to the data interface 124 shown in FIG. 1B.

The spatial, or spatiotemporal, sensors 540 detect the spatial position, movement, or both, of the image capture apparatus 500. As shown in FIG. 5, the spatial sensors 540 include a position sensor 542, an accelerometer 544, and a gyroscope 546. The position sensor 542, which may be a global positioning system (GPS) sensor, may determine a geospatial position of the image capture apparatus 500, which may include obtaining, such as by receiving, temporal data, such as via a GPS signal. The accelerometer 544, which may be a three-axis accelerometer, may measure linear motion, linear acceleration, or both of the image capture apparatus 500. The gyroscope 546, which may be a three-axis gyroscope, may measure rotational motion, such as a rate of rotation, of the image capture apparatus 500. In some implementations, the spatial sensors 540 may include other types of spatial sensors. In some implementations, one or more of the position sensor 542, the accelerometer 544, and the gyroscope 546 may be omitted or combined.

The power components 550 distribute electrical power to the components of the image capture apparatus 500 for operating the image capture apparatus 500. As shown in FIG. 5, the power components 550 include a battery interface 552, a battery 554, and an external power interface 556 (ext. interface). The battery interface 552 (bat. interface) operatively couples to the battery 554, such as via conductive contacts to transfer power from the battery 554 to the other electronic components of the image capture apparatus 500. The battery interface 552 may be similar to the battery receptacle 126 shown in FIG. 1B. The external power interface 556 obtains or receives power from an external source, such as a wall plug or external battery, and distributes the power to the components of the image capture apparatus 500, which may include distributing power to the battery 554 via the battery interface 552 to charge the battery 554. Although one battery interface 552, one battery 554, and one external power interface 556 are shown in FIG. 5, any number of battery interfaces, batteries, and external power interfaces may be used. In some implementations, one or more of the battery interface 552, the battery 554, and the external power interface 556 may be omitted or combined. For example, in some implementations, the external interface 556 and the I/O interface 532 may be combined.

The user interface components 560 receive input, such as user input, from a user of the image capture apparatus 500, output, such as display or present, information to a user, or both receive input and output information, such as in accordance with user interaction with the image capture apparatus 500.

As shown in FIG. 5, the user interface components 560 include visual output components 562 to visually communicate information, such as to present captured images. As shown, the visual output components 562 include an indicator 564 and a display 566. The indicator 564 may be similar to the indicator 106 shown in FIG. 1A, the indicators 208 shown in FIGS. 2A-2B, or the indicator 406 shown in FIG. 4A. The display 566 may be similar to the display 108 shown in FIG. 1A, the display 142 shown in FIG. 1B, the display 224 shown in FIG. 2B, or the display 424 shown in FIG. 4A. Although the visual output components 562 are shown in FIG. 5 as including one indicator 564, the visual output components 562 may include multiple indicators. Although the visual output components 562 are shown in FIG. 5 as including one display 566, the visual output components 562 may include multiple displays. In some implementations, one or more of the indicator 564 or the display 566 may be omitted or combined.

As shown in FIG. 5, the user interface components 560 include a speaker 568. The speaker 568 may be similar to the speaker 138 shown in FIG. 1B, the audio components 218, 220, 222 shown in FIGS. 2A-2B, or the audio components 418, 420, 422 shown in FIGS. 4A-4B. Although one speaker 568 is shown in FIG. 5, the user interface components 560 may include multiple speakers. In some implementations, the speaker 568 may be omitted or combined with another component of the image capture apparatus 500, such as the microphone 514.

As shown in FIG. 5, the user interface components 560 include a physical input interface 570. The physical input interface 570 may be similar to the mode buttons 110, 210, 410 shown in FIGS. 1A, 2A, and 4A or the shutter buttons 112, 212, 412 shown in FIGS. 1A, 2B, and 4A. Although one physical input interface 570 is shown in FIG. 5, the user interface components 560 may include multiple physical input interfaces. In some implementations, the physical input interface 570 may be omitted or combined with another component of the image capture apparatus 500. The physical input interface 570 may be, for example, a button, a toggle, a switch, a dial, or a slider.

As shown in FIG. 5, the user interface components 560 include a broken line border box labeled “other” to indicate that components of the image capture apparatus 500 other than the components expressly shown as included in the user interface components 560 may be user interface components. For example, the microphone 514 may receive, or capture, and process audio signals to obtain input data, such as user input data corresponding to voice commands. In another example, the image sensor 512 may receive, or capture, and process image data to obtain input data, such as user input data corresponding to visible gesture commands. In another example, one or more of the spatial sensors 540, such as a combination of the accelerometer 544 and the gyroscope 546, may receive, or capture, and process motion data to obtain input data, such as user input data corresponding to motion gesture commands.

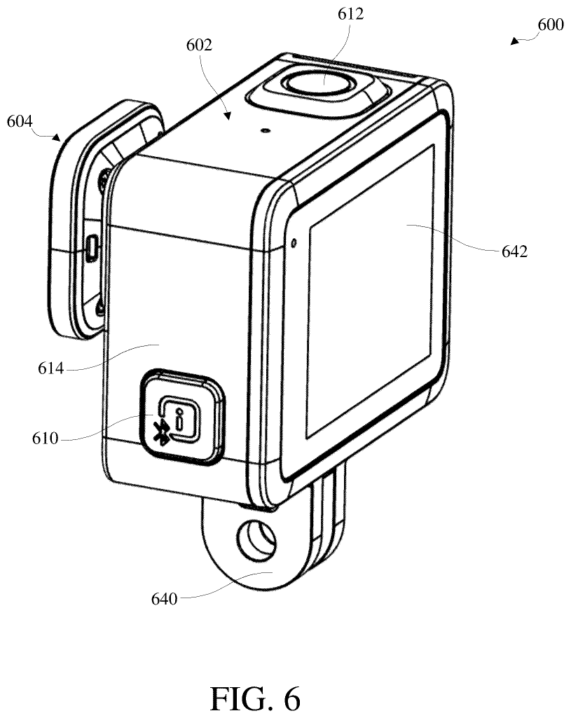

FIG. 6 is an isometric view of another example of an image capture apparatus 600. The image capture apparatus 600 may be similar to the image capture apparatuses 100, 200, 300, 400 described above.

The image capture apparatus 600 may include a body 602. The body 602 may define a central portion of the image capture apparatus 600. For example, the body 602 may define a least a portion of the overall shape of the image capture apparatus 600. The body 602 may also contain and/or connect one or more components of the image capture apparatus 600 to facilitate operation of the image capture apparatus 600.

An image capture device 604, a mode button 610, and a shutter button 612 may be coupled to or otherwise formed with the body 602. For example, the body 602 may include a housing 614 that forms an outer casing of the body 602 and defines a cavity therein. The image capture device 604 may extend through the housing 614 such that at least a portion of the image capture device 604 is located within the housing 614 (e.g., within the cavity of the housing 614).

Similarly, the mode button 610 and the shutter button 612 may be integrated into, or coupled to, the housing 614 such that the mode button 610 and the shutter button 612 may interact with respective internal components of the image capture apparatus 600 that are located within the housing 614. For example, the mode button 610 may be pressed by a user to modify an operating mode of the image capture apparatus 600. Similarly, the shutter button 612 may be pressed by the user to capture an image and/or video with the image capture device 604. However, the above functionality of the mode button 610 and the shutter button 612 are only examples and not intended to limit possible operations of the mode button 610 and the shutter button 612.

The image capture apparatus 600 may also be configured for mounting to one or more structures, accessories, or the like. The image capture apparatus 600 may include an interconnect mechanism 640 that may be used to secure the image capture apparatus 600 to the structures, accessories, or the like. For example, the interconnect mechanism 640 may be or may include one or more fingers that are configured to be received by a bracket or secondary mount such that the one or more fingers may be secured to the bracket or secondary mount by a fastener. As shown in FIG. 6, the interconnect mechanism 640 may be a pair of fingers that extends from the body 602 of the image capture apparatus 600. The interconnect mechanism 640 may be coupled to, or extend through, the housing 614 to secure the interconnect mechanism 640 to the body 602.

The image capture apparatus 600 may also include a display 642. The display 642 may be disposed on a surface of the housing 614 or integrated with a surface of the housing 614. For example, as shown in FIG. 6, the display 642 may be located on a first surface of the housing 614 that opposes a second surface of the housing 614 which includes the image capture device 604. The display 642 may allow a user to view images and/or videos captured by the image capture device 604. The display 642 may also provide the user an interface (e.g., a touchscreen) to adjust one or more settings of the image capture apparatus 600. Thus, based on the above, the image capture apparatus 600 may provide an integrated device for a user to easily capture images and/or videos.

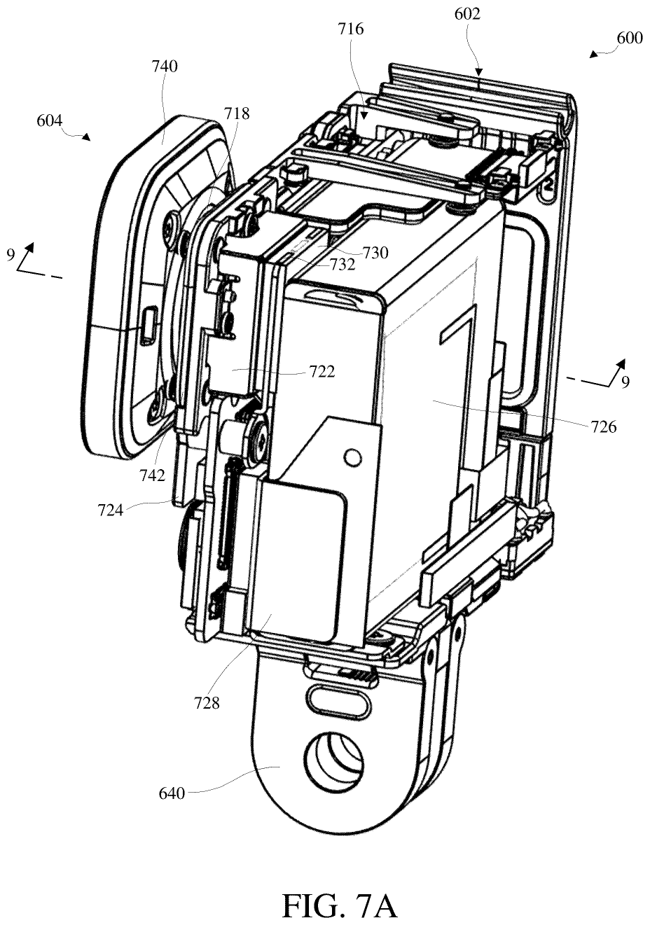

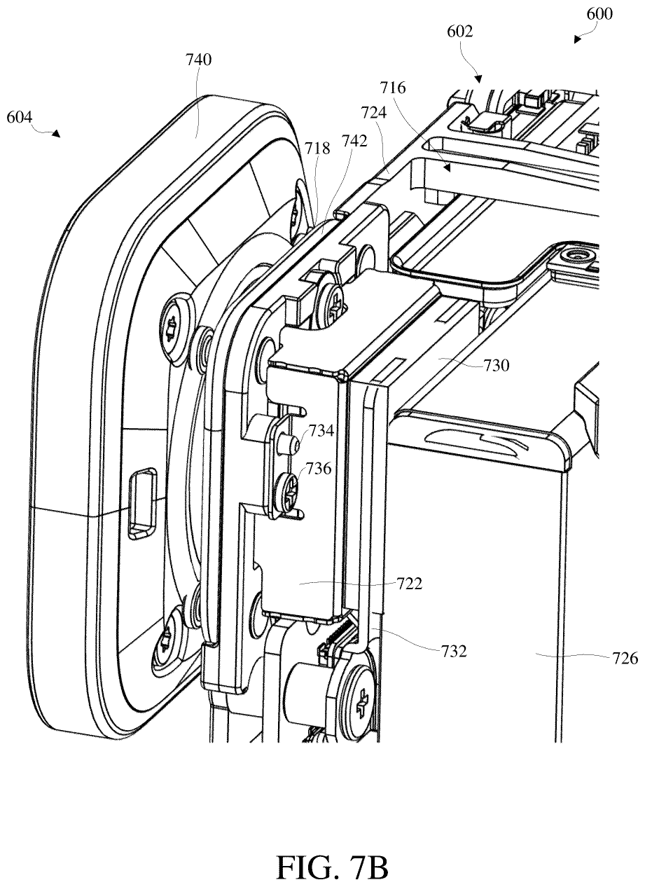

FIG. 7A is an isometric view of the image capture apparatus 600 shown in FIG. 6. FIG. 7B is a close-up view of the image capture apparatus 600 shown in FIG. 6. The housing 614 of the image capture apparatus 600 is removed in FIGS. 7A and 7B for illustrative purposes.

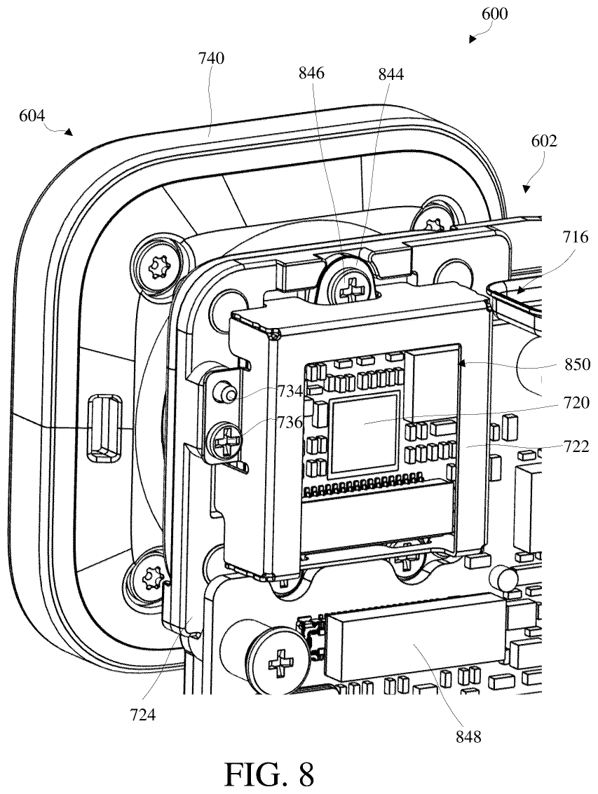

As discussed above, the body 602 of the image capture apparatus 600 may include the housing 614, whereby the housing 614 may define a cavity 716 therein. Contents of the cavity 716 are shown in FIGS. 7A and 7B since the housing 614 is removed. The image capture device 604 may extend through the housing 614 and into the cavity 716. By way of example, the image capture device 604 may include a lens barrel 718 that extends through the housing 614 and into the cavity 716. As discussed further below, the lens barrel 718 may be aligned with an image sensor 720 (FIG. 8) of the image capture device 604 that is located within the cavity 716 of the housing 614 so that content captured through the lens barrel 718 (e.g., through the lenses) is received by the image sensor 720 that is configured to convert the content into a digital image.

As discussed above, electronic interference, such as electromagnetic radiation, may negatively affect the performance of the image capture device 604. For example, electromagnetic waves emitted by electronic components of the image capture apparatus 600, by other devices external to the image capture apparatus 600, or by other sources may negatively affect the image sensor 720, which may as a result negatively impact resulting video and/or digital images.

To combat such interference, the image capture device 604 may include a shield 722 that is located in the cavity 716 of the housing 614. The shield 722 may at least partially enclose the image sensor 720 to block electromagnetic waves generated external to the image sensor 720 from reaching the image sensor 720. The shield 722 may provide electromagnetic frequency (EMF) shielding for the image sensor 720 so that the electromagnetic waves are prevented from interfering with operation of the image sensor 720 and/or the image capture device 604 as a whole. That is, the shield 722 may deflect and/or absorb the interfering electromagnetic waves to keep such waves away from the image sensor 720. As a result, the shield 722 may ensure proper operation of the image sensor 720 to enable accurate conversion of content captured by the image capture device 604 (e.g., content captured through the lens barrel 718) into video or a digital image free of distortion or blurriness.

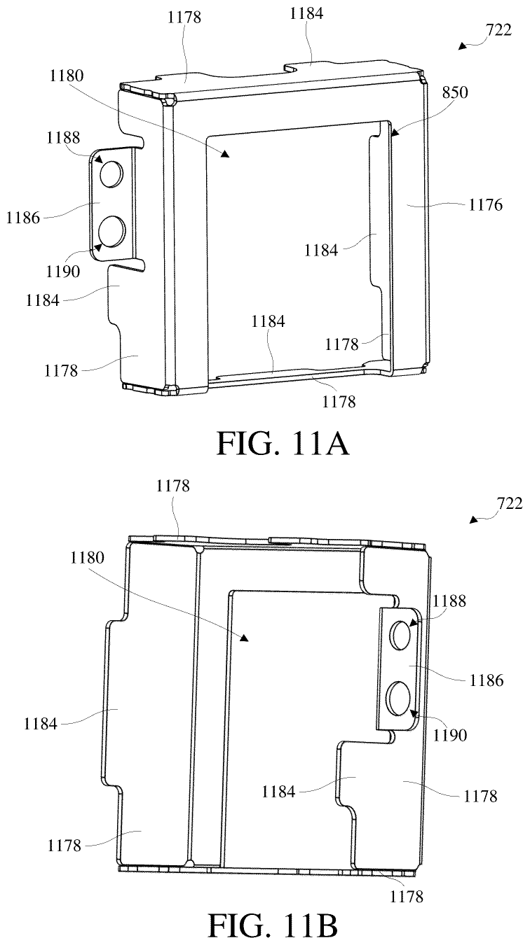

The shield 722 may also act as an EMF barrier for the image sensor 720 to contain electronic interference caused or generated by the image sensor 720. As discussed above, the shield 722 may at least partially enclose the image sensor 720. As a result, the shield 722 may be configured to deflect and/or absorb electromagnetic waves emitted by the image sensor 720 such that the electromagnetic waves emitted by the image sensor 720 are contained within the cavity 1180 (FIG. 11) of the shield 722. Due to such containment, the shield 722 may protect other electronic components of the image capture apparatus 600 from interference that may be caused by the electromagnetic waves emitted by the image sensor 720.

The shield 722 may be coupled to a heat sink 724 of the image capture apparatus 600. The heat sink 724 may be located in the cavity 716 of the housing 614 and may contact the image capture device 604. For example, the heat sink 724 may be coupled to a portion of the image capture device 604, such as the lens barrel 718, the image sensor 720, other components of the image capture device 604, or a combination thereof to secure the image capture device 604 to the body 602 of the image capture apparatus 600. Based on such contact between the heat sink 724 and the image capture device 604, the heat sink 724 may be configured to absorb heat generated by the image capture device 604 to maintain and/or decrease an operating temperature of the image capture device 604.

For example, during operation of the image capture device 604 (e.g., during image and/or video capturing), heat generated by the image capture device 604 (e.g., heat generated by the image sensor 720 and other electronic components) may be absorbed by the heat sink 724, whereby the heat sink 724 may in turn transfer the absorbed heat to the shield 722 and/or dissipate the absorbed heat to maintain, increase, and/or decrease a temperature of the image capture device 604.

During certain operating conditions, the heat sink 724 may also be configured to absorb (e.g., receive) heat from the shield 722 to decrease a temperature of the image capture apparatus 600. By way of example, the image capture apparatus 600 may also include a power module 726 (e.g., a battery) located in the cavity 716 of the housing 614 that is configured to power the image capture apparatus 600 or components thereof (e.g., the image capture device 604). As shown in FIGS. 7A and 7B, the shield 722 may be positioned between the heat sink 724 and the power module 726. Similarly, at least a portion of the shield 722 may also be positioned between the image sensor 720 and the power module 726.

As discussed above, the heat sink 724 may absorb heat generated by the image capture device 604 during operation of the image capture device 604 and transfer such heat to the shield 722 for dissipation of the heat. However, in other operating conditions, such as during charging of the of the power module 726 when the image capture apparatus 600 is not in use, heat may be generated by the power module 726. In such a case, the shield 722 may act as a secondary heat sink for the power module 726 to absorb the heat generated by the power module 726, either directly from the power module 726 or through an intermediary component, such as a power module bracket 728 that couples the power module 726 to the body 602 of the image capture apparatus 600. The shield 722 may then transfer the heat absorbed from the power module 726 to the heat sink 724 for dissipation of the heat. Thus, based on the above, heat may be transferred between the heat sink 724 and the shield 722 in opposing directions based upon operating conditions of the image capture apparatus 600.

Further cooling means may also be implemented in the image capture apparatus 600. For example, the image capture apparatus 600 may also include a spacer 730 coupled to the body 602 of the image capture apparatus 600 via a spacer bracket 732. The spacer 730 may be located between the power module 726 and the shield 722 to at least partially insulate the image capture device 604 (e.g., the image sensor 720) from heat generated by the power module 726. That is, the shield 722 may be spaced apart from the power module 726 such that the spacer 730 may be located therebetween. While the spacer 730 is not particularly limited to any one type of material, the spacer 730 may be made from a thermal insulative material such as fiberglass, wool, foam, cellulose, a reflective insulating material (e.g., aluminum foil), the like, or a combination thereof. Thus, the spacer 730 may provide further means to maintain a temperature of the image capture apparatus 600 and prevent unwanted heat transfer between the power module 726 and the image capture device 604.

As discussed above, the shield 722 may be coupled to the heat sink 724 and/or one or more other portions of the image capture apparatus 600 to maintain a position of the shield 722 within the cavity 716 of the housing 614. For example, as shown in FIG. 7B, the heat sink 724 may be directly coupled to the shield 722 to encapsulate the image sensor 720 between the heat sink 724 and the shield 722. A pin 734 projecting from the heat sink 724 may align with, and be received by, an aperture of the shield 722 to properly align the shield 722 with the heat sink 724. Additionally, one or more fasteners, such as a shield fastener 736 may extend through the shield 722 (e.g., through an aperture of the shield 722) and into the heat sink 724 to secure the shield 722 to the heat sink 724. However, the shield 722 and/or the heat sink 724 may include any means of mechanically coupling the shield 722 to the heat sink 724. Moreover, the shield 722 may also be adhesively secured to the heat sink 724.

As discussed above, a portion of the image capture device 604 (e.g., the lens barrel 718) may extend into the cavity 716 of the housing 614. Additionally, another portion of the image capture device 604 may also be positioned external to the housing 614 of the image capture apparatus 600. That is, a portion of the image capture device 604 may extend into the cavity 716 of the housing 614 such that another portion of the image capture device 604 may be positioned outward of the body 602 and the housing 614 of the image capture apparatus 600.

For example, as shown in FIGS. 7A and 7B, the image capture device 604 may also include a removable lens cover 740. The removable lens cover 740 may be coupled to any portion of the image capture device 604 and/or any portion of the body 602 of the image capture apparatus 600. For example, the removable lens cover 740 may be coupled directly to the lens barrel 718. Alternatively, or additionally, the removable lens cover 740 may be coupled to the heat sink 724 in a manner that facilitates easy connection and disconnection of the removable lens cover 740 from image capture apparatus 600, which is described further below. As a result, the removable lens cover 740 may be easily replaceable and/or interchangeable without requiring disassembly of the image capture device 604.

Connection of the removable lens cover 740 may be done in a manner that prevents water and/or debris from entering between the removable lens cover 740 and the body 602 of the image capture apparatus 600. For example, a seal 742 may be positioned between the removable lens cover 740 (e.g., between a body that supports a lens of the removable lens cover 740) and the heat sink 724 to provide protection from moisture and/or debris.

FIG. 8 illustrates a close-up perspective view of the image capture device 604 shown in FIGS. 6 and 7A-7B. Components such as the housing 614 and the power module 726 of the image capture apparatus 600 are removed for illustrative purposes only.

As discussed above, the image capture device 604 may include a lens barrel 718 that extends through portions of the body 602 of the image capture apparatus 600. For example, the lens barrel 718 may extend through the housing 614 and through the heat sink 724 of the image capture apparatus 600. To secure the lens barrel 718 and thus the image capture device 604 to the body 602 of the image capture apparatus 600, the lens barrel 718 may be secured to the body 602 by a lens barrel mount 844.

As shown in FIG. 8, the lens barrel mount 844 may be located in the cavity 716 of the housing 614 and mounted to the heat sink 724 by a lens barrel mount fastener 846 to secure the image capture device 604 to the body 602 of the image capture apparatus 600. However, any coupling means (e.g., adhesive, mechanical interlock, etc.) may be used to secure the lens barrel mount 844 to the heat sink 724. Similarly, the lens barrel mount 844 may also be coupled to a portion of the body 602 other than the heat sink 724, such as the housing 614, the shield 722, or other components.

The lens barrel mount 844 may also facilitate alignment between the lens barrel 718 and the image sensor 720. By way of example, the image sensor 720 and the lens barrel 718 may both be coupled to the lens barrel mount 844 to maintain alignment between the image sensor 720 and the lens barrel 718. For example, as shown in FIG. 8, the image sensor 720 may be coupled to a first (e.g., inboard) side of the lens barrel mount 844 while the lens barrel 718 may be coupled to an opposing second (e.g., outboard) side of the lens barrel mount 844. As a result, the image capture device 604 may be secured to the body 602 of the image capture apparatus 600 such that the lens barrel 718 may extend outward from the body 602 to align with the removable lens cover 740 while the image sensor 720 remains positioned within the cavity 716 of the housing 614.

Based on the above mounting technique, the image sensor 720 and a portion of the lens barrel mount 844 may be located between the heat sink 724 and the shield 722. That is, shield 722 and the lens barrel mount 844 may be coupled to the heat sink 724 such that the image sensor 720 and at least a portion of the lens barrel mount 844 are positioned in the cavity 1180 (FIG. 11) defined by the shield 722. Thus, a position of the image sensor 720 may be maintained to ensure alignment of the image capture device 604 while the shield 722 may provide protection to the image sensor 720 from electronic interference. Additionally, the lens barrel mount 844 may facilitate mounting the image sensor 720 in a location that is close in proximity to the power module 726 shown in FIGS. 7A and 7B, to a printed circuit board (PCB) 848 of the image capture apparatus 600, or both. For example, the shield 722 may include an opening 850 that permits access to the cavity 1180 (FIG. 11) of the shield 722 such that the image sensor 720 may be easily coupled to the PCB 848 (e.g., via one or more connectors) to ensure communication between the image sensor 720 and the PCB 848. Similarly, the opening 850 may permit access to the cavity 1180 (FIG. 11) of the shield 722 such that the image sensor 720 may be directly or indirectly powered by the power module 726.

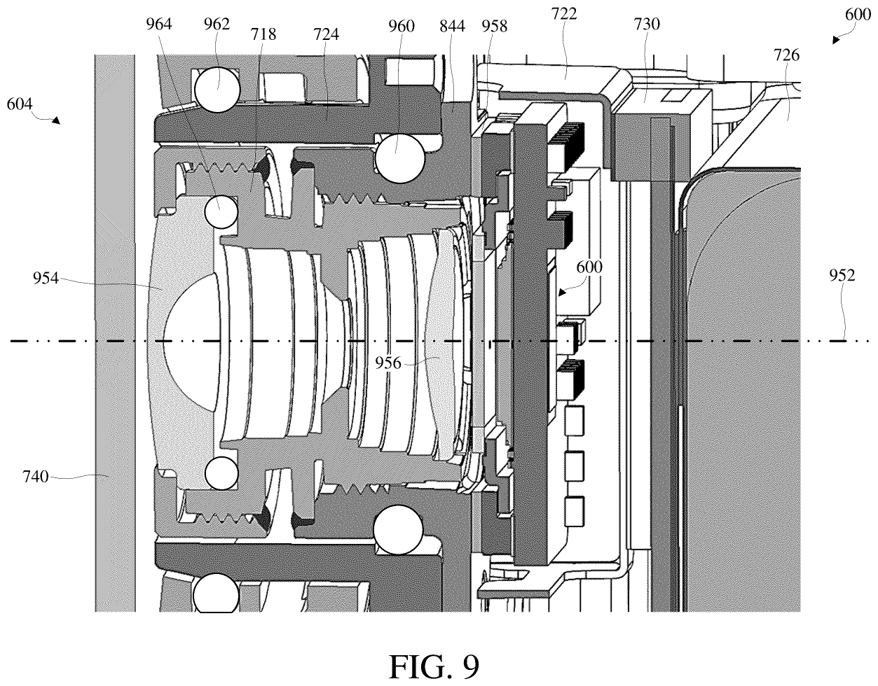

FIG. 9 illustrates a cross-sectional view of the image capture apparatus 600 shown in FIG. 7A taken along line 9-9. As shown in FIG. 9 and discussed above with respect to FIGS. 7A-8, the image capture apparatus 600 may include an image capture device 604 coupled to the body 602 of the image capture apparatus 600. The image capture device 604 may be coupled to the body 602 via the lens barrel mount 844. That is, the lens barrel 718 and/or the image sensor 720 may be coupled to the lens barrel mount 844, whereby the lens barrel mount 844 may be coupled to a portion of the body 602 of the image capture apparatus 600, such as the heat sink 724.

As shown in FIG. 9, the lens barrel mount 844 may facilitate alignment of the image capture device 604 along an optical axis 952 of the image capture device 604. That is, the lens barrel mount 844 may mount the lens barrel 718 and the image sensor 720 to the heat sink 724 such that the lens barrel 718, the image sensor 720, and the removable lens cover 740 are aligned along the optical axis 95. As such, the lens barrel mount 844 may be configured align the lens barrel 718 along the optical axis 952 of the image capture device 604 when the lens barrel mount 844 is mounted to the heat sink 724 to ensure that the image sensor 720 received content through the lens barrel 718 free of distortion and/or blurriness.

By way of example and as shown in FIG. 9, lens barrel 718 may include a first lens 954 (e.g., outermost lens) and a second lens 956 (innermost lens), though the lens barrel 718 may also include more or less lenses than shown. When the lens barrel 718 is coupled to the heat sink 724 via the lens barrel mount 844, the first lens 954, the second lens 956, the removable lens cover 740, and the image sensor 720 may be aligned along the optical axis 952 of the image capture device 604. As a result, the image capture device 604 may accurately capture images and/or video.

Additionally, as discussed above, the image sensor 720 may be at least partially contained within the shield 722 between the shield 722 and the heat sink 724 to protect the image sensor 720 from electronic interference. Moreover, the shield 722 may be spaced apart from the power module 726 via a spacer 730 located therebetween. Based on such a configuration, heat may be effectively transferred between the image capture device 604, the heat sink 724, and the shield 722 to dissipate heat generated by the image capture device 604 during image capturing. Similarly, heat may be effectively transferred between the power module 726, the shield 722, and the heat sink 724 to dissipate heat generated by the power module 726. Thus, the configuration shown in FIG. 9 may provide effective heat transfer along different flow paths (e.g., from the heat sink 724 to the shield 722 and/or from the shield 722 to the heat sink 724) to maintain an operating temperature of the image capture apparatus 600.

Coupling of the image capture device 604 to the body 602 of the image capture apparatus 600 may be done in any desired mechanical or adhesive manner. That is, the lens barrel 718 and/or the image sensor 720 may be coupled to the lens barrel mount 844 in any manner. By way of example and as shown in FIG. 9, the lens barrel 718 may be mechanically coupled to the lens barrel mount 844 via threaded engagement. Additionally, the image sensor 720 may be coupled to the lens barrel mount 844 via an adhesive 958 disposed therebetween. However, such a configuration is not intended to limit the means of securing the image capture device 604 to the lens barrel mount 844.

Coupling of the image capture device 604 to the body 602 of the image capture apparatus 600 may also be done in a manner that inhibits or prevents moisture and/or debris from penetrating connection points between various components. That is, the configuration described above may inhibit or prevent moisture and/or debris from entering internal portions of the image capture device 604 and/or the image capture apparatus 600 that may cause degradation to the image capture apparatus 600 and negatively affect performance of the image capture apparatus 600.

By way of example, the image capture apparatus 600 may include one or more seals that provide a barrier for moisture and/or debris. For example, the image capture apparatus 600 may include a lens barrel mount seal 960 that is located between the lens barrel mount 844 and the heat sink 724. The image capture apparatus 600 may also include a lens cover seal 962 that is located between the removable lens cover 740 and the heat sink 724. Moreover, the image capture apparatus 600 may include a lens seal 964 that is located between the first lens 954 and the lens barrel 718. The above seals are not limited to any one configuration and are intended to provide moisture and/or debris protection between the components described above.

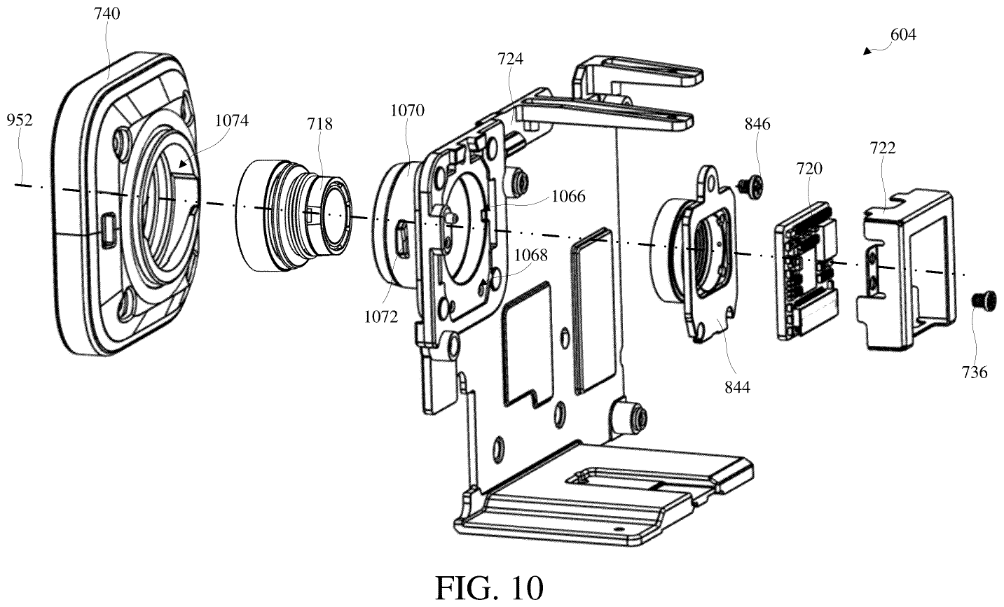

FIG. 10 illustrates an exploded view of an image capture device 604 shown in FIGS. 6-9. As discussed above, the image capture device 604 may include the lens barrel 718 and the image sensor 720, which may both be coupled to the heat sink 724 via the lens barrel mount 844. For example, the lens barrel 718 and the image sensor 720 may be secured to the lens barrel mount 844, and the lens barrel mount 844 may be coupled to the heat sink 724 via the lens barrel mount fastener 846 or a plurality thereof. The removable lens cover 740 may also be coupled to the heat sink 724 such that the removable lens cover 740, the lens barrel 718, and the image sensor 720 are all aligned along the optical axis 952 of the image capture device 604. As such, the image capture device 604 may capture images and/or video free of distortion or blurriness. The shield 722 may also at least partially encapsulate the image sensor 720 to prevent electronic interference with the image sensor 720 and further ensure that the image capture device 604 may capture images and/or video free of distortion or blurriness.

As discussed above, interconnection of the components of the image capture device 604 may be done in a variety of manners. However, for illustrative purposes, the mounting technique shown in FIG. 10 will be discussed in further detail.

As shown in FIG. 10, the lens barrel 718 may extend through the heat sink 724 such that the lens barrel 718 may be received by the lens barrel mount 844 to couple to the lens barrel 718 to the lens barrel mount 844. For example, the lens barrel 718 may extend through an aperture 1066 (e.g., an opening or barrel) of the heat sink 724 to engage the lens barrel mount 844. The image sensor 720 may also be coupled to the lens barrel mount 844 to align with the lens barrel 718 along the optical axis 952, such as via one or more fasteners or one or more adhesives (e.g., the adhesive 958 shown in FIG. 9). To secure the lens barrel 718 and the image sensor 720 to the heat sink 724, the lens barrel mount 844 may be coupled to the heat sink 724 via the lens barrel mount fastener 846 or a plurality thereof. For example, a receiving portion 1068 of the heat sink 724 may be complementary in shape to the lens barrel mount 844 to receive the lens barrel mount 844 and at least partially maintain a position of the lens barrel mount 844 when the lens barrel mount 844 is coupled to the heat sink 724. The shield 722 may then also be disposed over the image sensor 720 and at least a portion of the lens barrel mount 844 to secure the shield 722 to the heat sink 724 via the shield fastener 736.

The removable lens cover 740 may also be coupled directly to the heat sink 724 to align the removable lens cover 740 with the lens barrel 718 and the image sensor 720 along the optical axis 952. By way of example, the heat sink 724 may include a bayonet 1070 having one or more fingers 1072. The fingers 1072 of the bayonet 1070 may be received by a receiving portion 1074 of the removable lens cover 740 to releasable couple the removable lens cover 740 and the heat sink 724.

The components of the image capture device 604 described above may be assembled in any order relative to one another. For example, the removable lens cover 740 may be coupled to the heat sink 724 before or after coupling the lens barrel mount 844 to the heat sink 724.

FIGS. 11A and 11B illustrate perspective views of the shield 722 shown in FIGS. 7A-10. As discussed above, the shield 722 may be configured to at least partially enclose the image sensor 720 of the image capture device 604 to deflect and/or absorb electromagnetic waves, thereby inhibiting or preventing electronic interference with the image sensor 720.

As shown in FIGS. 11A and 11B, the shield 722 may include a front face 1176 and side faces 1178 connected to, and extending from, the front face 1176. The front face 1176 and the side faces 1178 may define an overall shape of the shield 722 and may further define a cavity 1180 of the shield 722. That is, the image sensor 720 of the image capture device 604 may be located in the cavity 1180 of the shield 722 when the image capture device 604 is coupled to the body 602 of the image capture apparatus 600. As a result, the image sensor 720 may be protected from external electronic interference.

Additionally, the front face 1176 may define the opening 850 of the shield 722 discussed above. The opening 850 may permit access to the cavity 1180 such that the image sensor 720 may be accessed to electrically connect the image sensor 720 to other hardware of the image capture apparatus 600, such as the PCB 848. However, the opening 850 may also be defined by the side faces 1178 and/or the shield 722 may also define a plurality of openings similar to the opening 850.

To mount the shield 722 to the body 602 of the image capture apparatus 600 (e.g., to the heat sink 724), the shield 722 may include one or more alignment features 1184. By way of example, the side faces 1178 may each include one of the alignment features 1184 that is received by a respective receiving feature of the heat sink 724. For example, the receiving portion 1068 of the heat sink 724 shown in FIG. 10 may include the receiving features that receive the alignment features 1184 of the shield 722. As a result, the shield 722 may be properly aligned with the heat sink 724 prior to securing the shield 722 to the heat sink 724.

To couple the shield 722 to the heat sink 724, the shield 722 may further include one or more tabs, such as the tab 1186. The tab 1186 may extend from one or more of the side faces 1178. To secure the shield 722 to the heat sink 724, the tab 1186 may define a first aperture 1188 and a second aperture 1190. The first aperture 1188 and the second aperture 1190 may vary in size and/or shape. For installation purposes, the first aperture 1188 may be configured to receive the pin 734 of the heat sink 724 shown in FIGS. 7A-8 to further align the shield 722 with the heat sink 724 and maintain a position of the shield 722. Additionally, the second aperture 1190 may be configured to receive the shield fastener 736 such that the shield fastener 736 may extend through the shield 722 and into a heat sink 724, thereby securing the shield 722 to the heat sink 724.

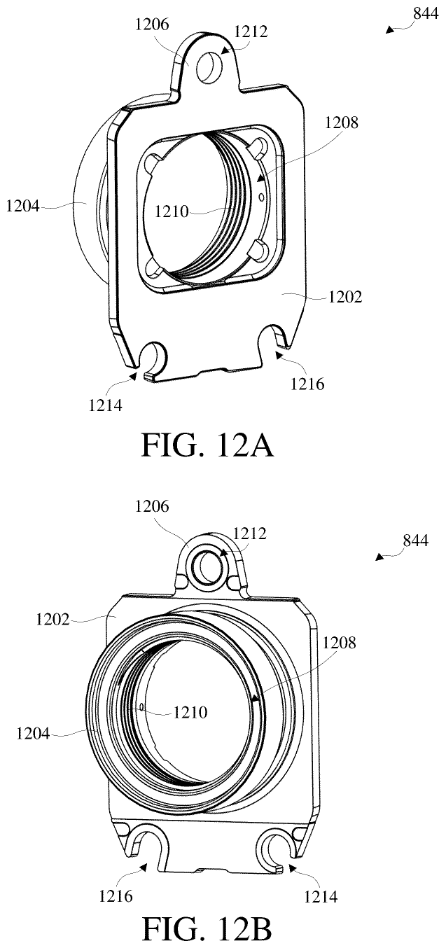

FIGS. 12A and 12B illustrate perspective views of the lens barrel mount 844 shown in FIGS. 8-10. As discussed above, the lens barrel mount 844 may be configured to secure the image capture device 604 (e.g., the lens barrel 718 and/or the image sensor 720) to the body 602 of the image capture apparatus 600.

As shown in FIGS. 12A and 12B, the lens barrel mount 844 may include a base 1202, a barrel 1204 extending from the base 1202, and a tab 1206 extending from the base 1202. The base 1202 and/or the barrel 1204 may define an opening 1208 therein that may be configured to receive and secure the lens barrel 718 to couple the lens barrel 718 to the heat sink 724. By way of example, the opening 1208 of the barrel 1204 may receive the lens barrel 718 such that threading located along an exterior surface of the lens barrel 718 may engage internal threading 1210 of the barrel 1204 to secure the lens barrel 718 to the lens barrel mount 844 (e.g., to the barrel 1204 of the lens barrel mount 844). As such, when the lens barrel mount 844 is secured to the heat sink 724 as described above, the barrel 1204 of the lens barrel mount 844 and the lens barrel 718 may be aligned along the optical axis 952 of the image capture device 604.

To secure the lens barrel mount 844 and thus the lens barrel 718 and the image sensor 720 to the heat sink 724, the lens barrel mount 844 may include one or more apertures. For example, as shown in FIGS. 12A and 12B, the lens barrel mount 844 may include a first aperture 1212, a second aperture 1214, and a third aperture 1216. The first aperture 1212 may be defined by the tab 1206 of the lens barrel mount 844 that extends from the base 1202. Additionally, the second aperture 1214 and the third aperture 1216 may be defined by the base 1202 and spaced apart from one another and/or spaced apart from the first aperture 1212. However, the apertures may be positioned anywhere along the lens barrel mount 844 with respect to one another to secure the lens barrel mount 844 to the heat sink 724.

The lens barrel mount 844 may be mounted to the heat sink 724 by fasteners extending through the first aperture 1212, the second aperture 1214, and the third aperture 1216 into the heat sink 724. As such, the first aperture 1212, the second aperture 1214, and the third aperture 1216 may provide a means for aligning the lens barrel mount 844 along the optical axis 952 to ensure proper alignment of the lens barrel 718 and the image sensor 720. To facilitate such alignment, the first aperture 1212, the second aperture 1214, and the third aperture 1216 may constrain translational movement of the lens barrel mount 844 along the optical axis 952, may constrain rotation movement of the lens barrel mount 844 about the optical axis 952, may constrain lateral translational movement with respect to the optical axis 952, or a combination thereof. As such, the lens barrel mount 844 may provide error-proofing that may prevent misalignment between the lens barrel mount 844 and the heat sink 724.

For example, the first aperture 1212, the second aperture 1214, the third aperture 1216, or a combination thereof may be shaped such that the fasteners may select align with respect their respective apertures. For example, the first aperture 1212, the second aperture 1214, the third aperture 1216, or a combination thereof may be tapered or otherwise shaped to ensure that the fasteners self-center within their respective apertures when the fasteners are tightened.

Positioning and/or sizing of the apertures may also provide means for aligning and/or constraining the lens barrel mount 844. For example, as shown in FIGS. 12A and 12B, the first aperture 1212 may be centered within the tab 1206 and include a circumference that is continuous and fully enclosed by tab 1206. Conversely, the second aperture 1214 may be positioned along an outer edge of the base 1202 such that a circumference of the second aperture 1214 is open to the outer edge of the base 1202. That is, the circumference may provide additional movement to its respective fastener when the fastener is positioned in the second aperture 1214. Similarly, the third aperture 1216 may be an open-ended and slotted hole that is positioned along the outer edge of the base 1202 to provide further movement to its respective fastener when the fastener is positioned in the third aperture 1216. As such, the apertures of the lens barrel mount 844 may allow for slight movement of the lens barrel mount 844 during installation yet may still ensure that the lens barrel mount 844 is correctly aligned with the heat sink 724 and thus also correctly aligned along the optical axis 952.

The methods and techniques of the image sensor mount and shielding described herein, or aspects thereof, may be implemented by an image capture apparatus, or one or more components thereof, such as the image capture apparatus 100 shown in FIGS. 1A-1B, the image capture apparatus 200 shown in FIGS. 2A-2B, the image capture apparatus 300 shown in FIG. 3, the image capture apparatus 400 shown in FIGS. 4A-4B, the image capture apparatus 500 shown in FIG. 5, or the image capture apparatus shown in FIGS. 6-9. The methods and techniques of the image sensor mount and shield described herein, or aspects thereof, may be implemented by an image capture device, such as the image capture device 104 shown in FIGS. 1A-1B, one or more of the image capture devices 204, 206 shown in FIGS. 2A-2B, one or more of the image capture devices 304, 306 shown in FIG. 3, the image capture device 404 shown in FIGS. 4A-4B, an image capture device of the image capture apparatus 500 shown in FIG. 5, or the image capture device 604 shown in FIGS. 6-10.

While the disclosure has been described in connection with certain emb6odiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. An image capture apparatus, comprising:
a housing defining a cavity therein;
an image capture device extending through the housing and that includes an image sensor located within the cavity of the housing;
a heat sink located in the cavity of the housing that contacts the image capture device, wherein the heat sink is configured to absorb heat generated by the image capture device; and
a shield located in the cavity of the housing that at least partially encloses the image sensor, wherein the shield is coupled to the heat sink and configured to block electromagnetic waves generated external to the image sensor from reaching the image sensor, and
wherein the heat sink is configured to transfer the heat generated by the image capture device to the shield.

2. The image capture apparatus of claim 1, wherein the image sensor is positioned between the heat sink and the shield.

3. The image capture apparatus of claim 1, wherein the image capture device includes a lens barrel that extends through the housing and extends through the heat sink.

4. The image capture apparatus of claim 1, further comprising:
a power module located in the cavity of the housing, wherein the shield is positioned between the heat sink and the power module.

5. The image capture apparatus of claim 4, wherein at least a portion of the shield is positioned between the image sensor and the power module.

6. The image capture apparatus of claim 4, wherein the shield is configured to transfer heat generated by the power module to the heat sink.

7. The image capture device of claim 4, wherein the shield is spaced apart from the power module such that a spacer made from a thermal insulative material is located therebetween.

8. The image capture device of claim 1, wherein the shield includes:
a front face defining an opening therein; and
side faces connected to the front face, wherein the front face and the side faces define a cavity of the shield, and the image sensor is located within the cavity of the shield.

9. The image capture device of claim 8, wherein the side faces each include an alignment feature that is received by a respective receiving feature of the heat sink.

10. The image capture device of claim 8, wherein the shield further includes a tab extending from one of the side faces that is configured to be coupled to the heat sink.

11. An image capture apparatus, comprising:
a housing defining a cavity therein;
a heat sink located in the cavity of the housing; and
an image capture device that includes:
a lens barrel extending through the housing and located at least partially within the cavity of the housing; and
a lens barrel mount configured to couple the lens barrel to the image capture apparatus, wherein the lens barrel mount includes:
a base;
a first aperture defined by a tab of the lens barrel mount that extends from the base;
a second aperture defined by the base; and
a third aperture defined by the base and spaced apart from the second aperture,
wherein the lens barrel mount is configured to be mounted to the heat sink by fasteners extending through the first aperture, the second aperture, and the third aperture into the heat sink.

12. The image capture apparatus of claim 11, wherein the second aperture is positioned along an outer edge of the base such that a circumference of the second aperture is open to the outer edge of the base.

13. The image capture apparatus of claim 12, wherein the third aperture is an open-ended and slotted hole.

14. The image capture apparatus of claim 11, wherein the lens barrel mount is configured to align the lens barrel along an optical axis of the image capture device when the lens barrel mount is mounted to the heat sink.

15. The image capture apparatus of claim 11, wherein the lens barrel mount further includes: a barrel extending from the base that defines an opening therein, wherein the barrel is configured to receive the lens barrel.

16. The image capture apparatus of claim 15, wherein the barrel of the lens barrel mount and the lens barrel are configured to be aligned along an optical axis of the image capture device.

17. An image capture apparatus, comprising:
a housing;
an image capture device that includes:
a lens barrel;
an image sensor; and
a lens barrel mount that includes:
a base; and
a barrel extending from the base that defines an opening therein that is configured to receive the lens barrel and align the lens barrel with an optical axis of the image capture device,
a heat sink located in the housing that contacts the image capture device; and
a shield located in the housing and that defines a cavity therein,
wherein the image sensor and the lens barrel mount are positioned in the cavity of the shield, and
wherein the image sensor is coupled to the lens barrel mount.

18. The image capture apparatus of claim 17, wherein the shield and the lens barrel mount are coupled to the heat sink.

19. The image capture apparatus of claim 17, wherein the image capture device further includes:
a removable lens cover that is coupled to the heat sink.

20. The image capture apparatus of claim 19, wherein the heat sink includes a bayonet that is configured to releasably couple the removable lens cover to the heat sink.
